(19) United States
(12) Patent Application Publication
(10) Pub. No.: US 2023/0141571 A1
(43) Pub. Date: May 11, 2023

(54) DRIVE APPARATUS AND DISTANCE MEASUREMENT SENSOR INCLUDING THE SAME

(71) Applicant: SAMSUNG ELECTRONICS CO., LTD., Suwon-si (KR)

(72) Inventors: Yong Sin KIM, Seoul (KR); Minseong KIM, Seoul (KR)

(73) Assignees: SAMSUNG ELECTRONICS CO., LTD., Suwon-si (KR); Korea University Research And Business Foundation, Seoul (KR)

(21) Appl. No.: 17/984,043

(22) Filed: Nov. 9, 2022

(30) Foreign Application Priority Data
Nov. 9, 2021 (KR) 10-2021-0153379
May 31, 2022 (KR) 10-2022-0066918

(51) Int. Cl. H01S 5/042; G01S 17/08

(52) U.S. Cl. CPC H01S 5/042; G01S 17/08

(57) ABSTRACT

Provided is a drive apparatus configured to drive an optical device. The drive apparatus includes a preprocessing circuit configured to generate a first reference signal by performing preprocessing on an input signal; a drive circuit configured to generate a driving current for driving the optical device, and generate a replica current based on the driving current; and a calibration circuit configured to generate a replica voltage signal based on the replica current, generate a driving signal by changing a phase of the first reference signal based on the replica voltage signal, and provide the driving signal to the drive circuit.

### CROSS-REFERENCE TO RELATED APPLICATIONS

This application is based on and claims priority under 35 U.S.C. § 119 to Korean Patent Application No. 10-2021-0153379, filed on Nov. 9, 2021, and Korean Patent Application No. 10-2022-0066918, filed on May 31, 2022, in the Korean Intellectual Property Office, the disclosures of which are incorporated by reference herein in their entireties.

### BACKGROUND

The present disclosure relates to a drive apparatus, a method of operating the drive apparatus, and a distance measurement sensor including the same, and more particularly, to a drive apparatus and method for driving an optical device and a distance measurement sensor including the drive apparatus.

A distance measurement sensor measures the distance to a measurement object by transmitting signals, such as light, sound, and radio waves, and measures a return time of the signals reflected from a measurement object. Among the distance measurement sensors, a distance measurement sensor using light utilizes an optical device and a drive apparatus driving the same. One of the indicators for evaluating the performance of the distance measurement sensor is the maximum measurable distance. Distance measurement sensors using light, such as time of flight (ToF) sensors and light detection and ranging (LiDAR) sensors, need a drive apparatus that operates at a speed of 100 MHz and stably drives high power in order to increase the maximum measurable distance. However, when a drive apparatus for driving high power is used, an increasing rise/fall time of a driving current for driving an optical device may occur. This may cause a problem of lowering the distance measurement accuracy of the distance measurement sensor.

### SUMMARY

Provided are a drive apparatus for stably driving high power by reducing a rise/fall time of a driving current and reducing a timing mismatch between the driving current and a driving signal, which is generated due to a decrease in the rise/fall time of the driving current, and an operating method thereof.

According to an aspect of an example embodiment, a drive apparatus configured to drive an optical device, includes: a preprocessing circuit configured to generate a first reference signal by performing preprocessing on an input signal; a drive circuit configured to generate a driving current for driving the optical device, and generate a replica current based on the driving current; and a calibration circuit configured to generate a replica voltage signal based on the replica current, generate a driving signal by changing a phase of the first reference signal based on the replica voltage signal, and provide the driving signal to the drive circuit.

According to an aspect of an example embodiment, a distance measurement sensor includes: an optical device; a controller configured to generate at least one drive apparatus control signal; and a drive apparatus configured to generate a first driving current based on the at least one drive apparatus control signal and provide the first driving current to the optical device, wherein the drive apparatus includes: a drive circuit configured to generate a replica current based on the first driving current; and a calibration circuit configured to generate a replica voltage signal based on the replica current, generate a driving signal by changing a phase of the at least one drive apparatus control signal based on the replica voltage signal, and provide the driving signal to the drive circuit, wherein the drive circuit is further configured to generate a second driving current based on the driving signal, and provide the second driving current to the optical device, and a slew rate of the second driving current is greater than a slew rate of the first driving current.

According to an aspect of an example embodiment, a method of operating a drive apparatus configured to drive an optical device, includes: generating a first reference signal by performing preprocessing on an input signal; generating a replica current based on a driving current driving the optical device; generating a replica voltage signal based on the replica current; generating a phase difference signal by detecting a phase difference between the replica voltage signal and a driving signal; generating a calibrated driving signal by shifting a phase of the first reference signal based on the phase difference signal; and generating the driving current based on the calibrated driving signal.

### BRIEF DESCRIPTION OF THE DRAWINGS

The above and/or other aspect will be more clearly understood from the following detailed description of example embodiments taken in conjunction with the accompanying drawings in which:

FIG. 1 is a block diagram illustrating a drive apparatus and an optical device according to an embodiment;

FIG. 2 is a block diagram illustrating a drive circuit according to an embodiment;

FIG. 3 is a circuit diagram illustrating a first pre-emphasis circuit and a first main driver circuit according to an embodiment;

FIG. 4 is a circuit diagram illustrating a current-voltage conversion circuit according to an embodiment;

FIG. 5 is a block diagram illustrating a delay-locked loop (DLL) circuit according to an embodiment;

FIG. 6 is a calibration timing diagram according to an embodiment;

FIGS. 7A and 7B are diagrams illustrating a calibration result according to an embodiment;

FIGS. 8A and 8B are diagrams illustrating a calibration result according to an embodiment;

FIG. 9 is a flowchart illustrating a method of operating a drive apparatus, according to an embodiment; and

FIG. 10 is a block diagram illustrating a distance measurement sensor according to an embodiment.

### DETAILED DESCRIPTION

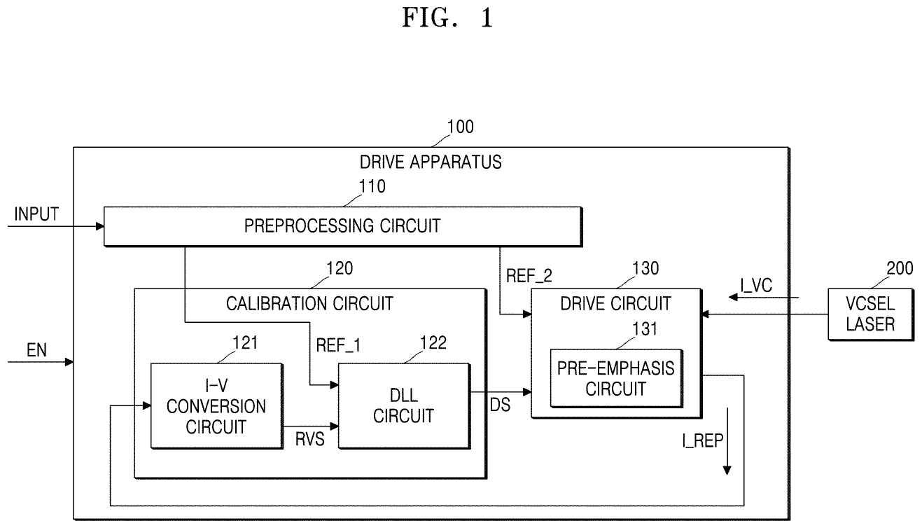

FIG. 1 is a block diagram illustrating a drive apparatus and an optical device according to an embodiment. According to an embodiment, an optical device 200 may be a vertical cavity surface emitting laser (VCSEL), but may be another light emitting device.

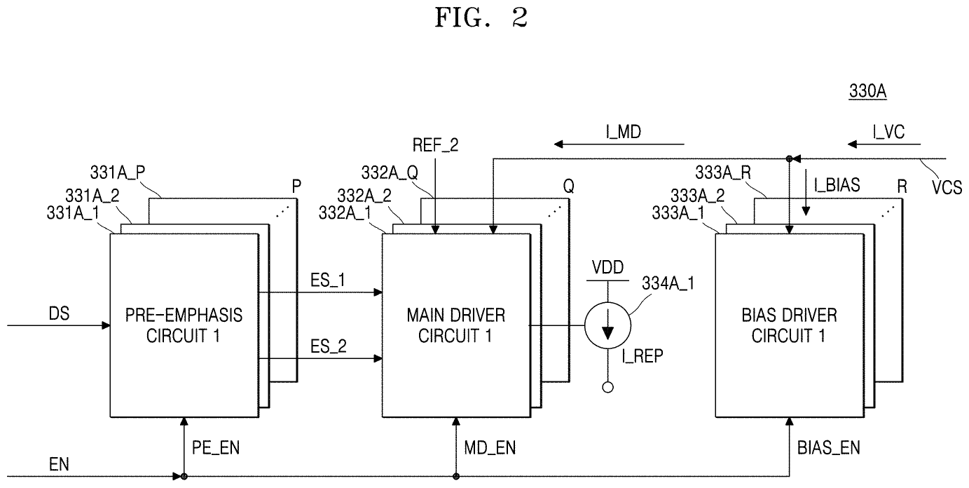

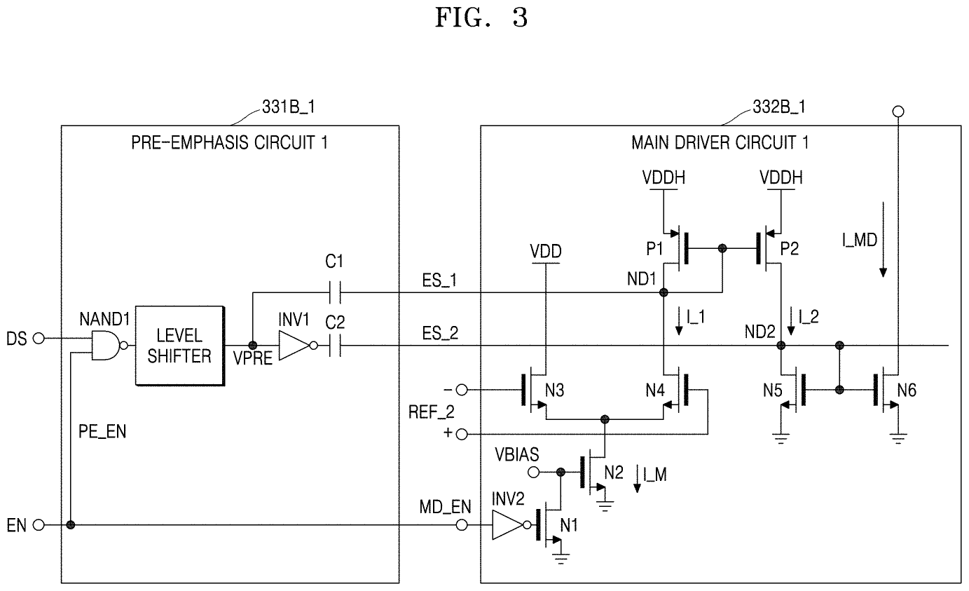

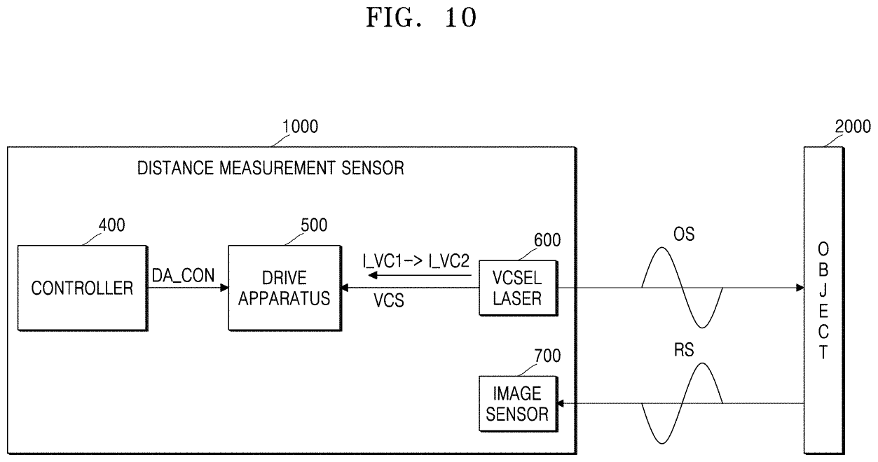

A drive apparatus 100 may receive the input signal INPUT from the outside (e.g., a controller 400 of FIG. 10). The input signal INPUT may be used to generate a driving current I_VC in a drive circuit 130 through a preprocessing circuit 110 or to reduce a timing mismatch between the driving current I_VC and a driving signal DS in a calibration circuit 120. In an embodiment, the drive apparatus 100 may further receive an enable signal EN from the outside. Referring to FIGS. 2 and 3, the enable signal EN may be used to adjust the current level flowing through the drive circuit 130.

In FIG. 1, the drive apparatus 100 may be an n-type metal-oxide-semiconductor (NMOS) drive apparatus as described below with reference to FIG. 3. Here, the NMOS drive apparatus may mean that a transistor (e.g., N6 in FIG. 3) for controlling the driving current I_VC is an NMOS transistor. However, this is only an example, and the drive apparatus 100 may be implemented as a p-type metal-oxide-semiconductor (PMOS) drive apparatus in which a transistor controlling the driving current I_VC is a PMOS transistor according to the optical device 200. When the drive apparatus 100 is a p-type metal oxide semiconductor (PMOS) drive apparatus, the driving current I_VC illustrated in FIG. 1 may flow from the drive apparatus 100 toward the optical device 200. The drive apparatus 100 may include the preprocessing circuit 110, the calibration circuit 120, and the drive circuit 130.

The preprocessing circuit 110 may generate a first reference signal REF1 and a second reference signal REF2 by performing preprocessing on the input signal INPUT. The preprocessing circuit 110 may amplify the input signal INPUT by performing preprocessing on the input signal INPUT. In addition, the preprocessing circuit 110 may reduce an effect of noise, which is generated by a circuit connected to the preprocessing circuit 110, influencing the input signal INPUT.

In an example embodiment, as shown in FIG. 6, the input signal INPUT may be a low voltage differential signal (LVDS) including a positive input signal P_INPUT and a negative input signal N_INPUT having a phase opposite to a phase of the positive input signal P_INPUT.

The first reference signal REF_1 may be provided to the calibration circuit 120 after the preprocessing circuit 110 converts the input signal INPUT from an analog signal to a digital signal. The second reference signal REF_2 may be obtained by the preprocessing circuit 110 temporarily storing and then outputting the input signal INPUT, that is, the preprocessing circuit buffers the input signal INPUT to provide, to the drive circuit 130, the buffered input signal INPUT, which is an analog signal.

Based on the positive input signal P_INPUT and the negative input signal N_INPUT, the first reference signal REF_1 may include a positive first reference signal and a negative first reference signal having a phase opposite to a phase of the positive first reference signal. Similarly, the second reference signal REF_2 may include a positive second reference signal and a negative second reference signal having a phase opposite to the phase of the positive second reference signal.

Referring to FIGS. 1 to 3, the drive circuit 130 may generate the driving current I_VC for driving the optical device 200, based on the second reference signal REF_2 and the driving signal DS.

The drive circuit 130 may increase the driving current I_VC flowing through the optical device 200 in order to increase the power of the optical device 200. When the driving current I_VC flowing through the optical device 200 increases, the rise/fall time of the driving current I_VC may increase.

The drive circuit 130 may include a pre-emphasis circuit 131 to reduce a rise/fall time of the driving current I_VC. Referring to FIGS. 1 to 3, the driving signal DS may be a signal for operating the pre-emphasis circuit 131. The pre-emphasis circuit 131 may instantaneously increase/decrease an amount of the driving current I_VC flowing in the optical device 200, based on the driving signal DS, thereby reducing a rise/fall time of the driving current I_VC. Since the drive apparatus 100 includes the pre-emphasis circuit 131, a propagation delay may occur in the drive apparatus 100. When a propagation delay occurs, a timing mismatch may occur between a rise/fall timing of the driving current I_VC and a timing when the pre-emphasis circuit 131 momentarily increases/decreases an amount of the driving current I_VC. When timing mismatch occurs, the rise/fall time of the driving current I_VC may not be sufficiently reduced.

The drive circuit 130 may generate the replica current I_REP based on the driving current I_VC driving the optical device 200. The replica current I_REP may be a signal having the same waveform as and different sizes/magnitudes from the driving current I_VC. For example, when the magnitude of the driving current I_VC is 1 A, the replica current I_REP may be a signal with the same waveform as the driving current I_VC but with a magnitude of 0.5 A. The drive circuit 130 may provide the generated replica current I_REP to the calibration circuit 120.

The calibration circuit 120 may include a current-voltage (I-V) conversion circuit 121 and a delay-locked loop (DLL) circuit 122.

The calibration circuit 120 may reduce a timing mismatch between the driving current I_VC and the driving signal DS for operating the pre-emphasis circuit 131. In other words, in the calibration circuit 120, the driving signal DS may be calibrated to instantaneously increase/decrease the driving current I_VC, according to the rise/fall timing of the driving current I_VC.

The current-voltage conversion circuit 121 may convert the replica current I_REP received from the drive circuit 130 into a replica voltage signal RVS. Since it difficult to use the driving current I_VC, which is an analog signal, in the DLL circuit 122 which is a digital circuit, the driving current I_VC may be converted into a replica voltage signal RVS by the current-voltage conversion circuit 121.

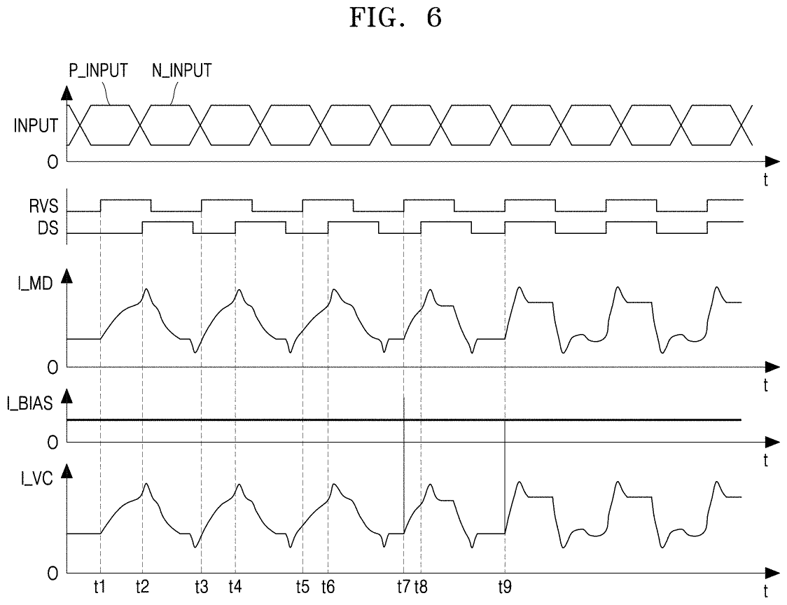

The DLL circuit 122 may receive the first reference signal REF1 and the replica voltage signal RVS. As shown in FIG. 5, the DLL circuit 122 may detect a phase difference between the driving signal DS and the replica voltage signal RVS to generate a phase difference signal P_DIFF. The DLL circuit 122 may generate a driving signal DS having calibrated timing based on the phase difference signal P_DIFF and the first reference signal REF1. The DLL circuit 122 may provide the timing calibrated driving signal DS to the drive circuit 130.

As will be described later, the drive apparatus 100 may drive high power and may stably reduce the rise/fall time of the driving current I_VC. In addition, the drive apparatus 100 may reduce a timing mismatch between the driving current I_VC and the driving signal DS, which is caused by a decrease in the rise/fall time of the driving current I_VC, and a maximum measurable distance of the distance measurement sensor including the drive apparatus 100 may be increased.

FIG. 2 is a block diagram illustrating a drive circuit according to an embodiment.

Referring to FIG. 2, a drive circuit 330A may include a plurality of pre-emphasis circuits 331A_1 to 331A_P, a plurality of main driver circuits 332A_1 to 332A_Q, a plurality of bias driver circuits 333A_1 to 333A_R, and a current mirror circuit 334A_1. In FIG. 2, operations of the first pre-emphasis circuit 331_1 among the pre-emphasis circuits 331A_1 to 331A_P, the first main driver circuit 332A_1 among the main driver circuits 332A_1 to 332A_Q, and the first bias driver circuit 333A_1 among the bias driver circuits 333A_1 to 333A_R are illustrated as an example. Operations of the second to P^{th} pre-emphasis circuits 331A_2 to 331A_P, the second to Q^{th} main driver circuits 332A 2 to 332A_Q, and the second to R^{th} bias driver circuits 333A_2 to 333A_R, respectively, may be described with reference to the first pre-emphasis circuit 331A_1, first main driver circuit 332A_1, and first main driver circuit 331A_1.

The drive circuit 330A may receive the enable signal EN from the outside. In an embodiment, the enable signal EN may be received by the drive apparatus 100 of FIG. 1 from a controller (e.g., 400 of FIG. 10) of the distance measurement sensor (e.g., 1000 of FIG. 10). The enable signal EN may include a pre-emphasis enable signal PE_EN, a main driver enable signal MD_EN, and a bias driver enable signal BIAS_EN. The pre-emphasis enable signal PE_EN, the main driver enable signal MD_EN, and the bias driver enable signal BIAS_EN may respectively have data corresponding to a number in which the pre-emphasis circuits 331A_1 to 331A_P, the main driver circuits 332A_1 to 332A_Q, and the bias driver circuits 333A_1 to 333A_R are enabled.

For example, when the pre-emphasis enable signal PE_EN has data corresponding to three, the main driver enable signal MD_EN has data corresponding to three, and the bias driver enable signal BIAS_EN has data corresponding to two, the first to third pre-emphasis circuits 331A_1 to 331A_3, the first to third main driver circuits 332A_1 to 332A_3, and the first and second bias driver circuits 333A_1 to 333A_2 may be enabled. In addition, the fourth to P^{th} pre-emphasis circuits 331A_4 to 331A_P, the fourth to Q^{th} main driver circuits 332A_4 to 332A_Q, and the third to R^{th} bias driver circuits 333A_3 to 333A_R may be disabled. The controller 400 of the distance measurement sensor 1000 may control the level of the driving current I_VC by adjusting the number of circuits enabled through the enable signal EN.

The first pre-emphasis circuit 331A_1 may generate a first emphasis signal ES_1 and a second emphasis signal ES_2 based on the driving signal DS, and the first main driver circuits 332A_1 may provide the first emphasis signal ES_1 and the second emphasis signal ES_2.

The first main driver circuit 332A_1 may generate the main driver current I_MD, based on the first emphasis signal ES_1, the second emphasis signal ES_2, and the second reference signal REF2 received from the preprocessing circuit 110 of FIG. 1.

The first bias driver circuit 333A_1 may generate a bias current I_BIAS. The bias current I_BIAS may have a constant current level as a direct-current (DC) current.

The current mirror circuit 334A_1 may be configured to receive a power supply voltage VDD and be connected to the first to Q^{th} main driver circuits 332A_1 to 332A_Q. The current mirror circuit 334A_1 may generate a replica current I_REP corresponding to the main driver current I_MD. The current mirror circuit 334A_1 may be connected to the current-voltage conversion circuit 121, and the replica voltage RCS may be output by the output terminal of the current mirror circuit 334A_1.

The driving current I_VC may be represented as a sum of the main driver current I_MD and the bias current I_BIAS. Since the bias current I_BIAS may be a DC current, the waveform of the main driver current I_MD may be the same as the waveform of the driving current I_VC. Accordingly, the waveform of the replica current I_REP may be the same as the waveform of the driving current I_VC.

FIG. 3 is a circuit diagram illustrating a first pre-emphasis circuit 331B_1 and a first main driver circuit 332B_1 according to an embodiment. In FIG. 3, the first pre-emphasis circuit 331B_1 and the first main driver circuit 332B_1 are illustrated as examples. Operations of the second to P^{th} pre-emphasis circuits 331B_2 to 331B_P and the second to Q^{th} main driver circuits 332B_2 to 332B_Q, respectively, may be described with reference to the first pre-emphasis circuit 331B_1 and first main driver circuit 332B_1.

Referring to FIGS. 1 and 3, the first pre-emphasis circuit 331B_1 may include a first NAND circuit NAND1, a level shifter, a first capacitor C1, a second capacitor C2, and a first inverter INV1.

The first pre-emphasis circuit 331B_1 may receive the driving signal DS from the calibration circuit 120 and receive the pre-emphasis enable signal PE_EN from the controller (e.g., 400 of FIG. 10) of the distance measurement sensor (e.g., 1000 of FIG. 10).

When the pre-emphasis enable signal PE_EN has a high logic level, the first NAND circuit NAND1 may transmit, to the level shifter, a signal performing a NAND operation between the driving signal DS and the pre-emphasis enable signal PE_EN. The level shifter may transfer, to the second capacitor C2 through the first capacitor C1 and the first inverter INV1, the pre-emphasis signal VPRE generated by shifting the voltage level of the signal received from the first NAND circuit NAND1. The first capacitor C1 and the second capacitor C2 may extract an alternating-current (AC) component of the received signal to generate a first emphasis signal ES_1 and a second emphasis signal ES_2, respectively, and may provide the generated first emphasis signal ES_1 and second emphasis signal ES_2 to the first main driver circuit 332B_1.

When the pre-emphasis enable signal PE_EN has a low logic level, the first NAND circuit NAND1 may output a signal of a constant high logic level regardless of the logic level of the driving signal DS. In addition, the pre-emphasis signal VPRE obtained by shifting the voltage level of the signal received by the level shifter from the first NAND circuit NAND1 may also have a constant high logic level. When the pre-emphasis signal VPRE has a constant voltage level, the pre-emphasis signal VPRE may not have an alternating-current (AC) component. In this case, since the first capacitor C1 and the second capacitor C2 may not generate the first and second emphasis signals ES_1 and ES_2 respectively, by extracting the AC component of the pre-emphasis signal VPRE, the first pre-emphasis circuit 331B_1 may be disabled.

The first main driver circuit 332B_1 may include first to sixth NMOS transistors N1 to N6, a first PMOS transistor P1, a second PMOS transistor P2, and a second inverter INV2. Since a transistor for controlling the main driver current I_MD, may be the sixth NMOS transistor N6 in the first main driver circuit 332B_1, the drive apparatus 100 including the first main driver circuit 332B_1 may be an NMOS drive apparatus.

The first main driver circuit 332B_1 may receive the main driver enable signal MD_EN from the controller 400, the second reference signal REF2 from the preprocessing circuit 110, and the first to second emphasis signals ES_1 and ES_2 from the first pre-emphasis circuit 331B_1.

A first power supply voltage VDD may be applied to the drain of the third NMOS transistor N3, and a negative second reference signal may be applied to the gate of the third NMOS transistor N3. In addition, the drain of the fourth NMOS transistor N4 may be connected to the first node ND1, and a positive second reference signal may be applied to the gate of the fourth NMOS transistor N4.

The sources of the third NMOS transistor N3 and the fourth NMOS transistor N4 may be commonly connected to the drain of the second NMOS transistor N2. Thus, assuming that a predetermined modulation current I_M flows in the second NMOS transistor N2, the third NMOS transistor N3, and the fourth NMOS transistor N4 may operate as differential amplifiers. A differential amplifier may refer to a circuit that amplifies a voltage difference between two input signals. That is, the first main driver circuit 332A_1 may apply, to a first node ND1, a voltage obtained by multiplying a gain of a differential amplifier by a voltage obtained by subtracting a negative second reference voltage applied to a gate of the third NMOS transistor from the second reference voltage. When the voltage applied to the gate of the third NMOS transistor N3 is N_PRE2, the voltage applied to the gate of the fourth NMOS transistor N4 is P_PRE2, and the second reference voltage that is the difference between the two voltages is VREF2 and a gain of the differential amplifier is A, the voltage applied to the first node ND1 may be represented as VNODE1=A*(P_PRE2−N_PRE2)=A*VREF2.

When the main driver enable signal MD_EN has a high logic level, a low logic level voltage may be applied to the gate of the first NMOS transistor N1 through the second inverter INV2, and the first NMOS transistor N1 may be turned off. A constant bias voltage VBIAS may be applied to the gate of the second NMOS transistor N2 to turn on the second NMOS transistor N2, and a ground voltage may be applied to the source electrodes of the third NMOS transistor N3 and the fourth NMOS transistor N4.

When the main driver enable signal MD_EN has a low logic level, a high logic level voltage may be applied to the gate of the first NMOS transistor N1 through the second inverter INV2, and the first NMOS transistor N1 may be turned on. In this case, a ground voltage is applied to the gate of the second NMOS transistor N2, and the second NMOS transistor N2 may be turned off. When the second NMOS transistor N2 is turned off, a constant adjustment current I_M may not flow in the second NMOS transistor N2, and thus, the third NMOS transistor N3 and the fourth NMOS transistor N4 may not operate as a differential amplifier.

Since the gate of the first PMOS transistor P1 may be connected to the source of the first PMOS transistor P1 and the gate of the second PMOS transistor P2, the first PMOS transistor P1 and the second PMOS transistor P2 may form a first current mirror. That is, the second current I_2 that is N times the first current I_1 flowing in the first PMOS transistor P1 may flow in the second PMOS transistor P2. Here, N may vary according to processes, structures, and the like of the first PMOS transistor P1 and the second PMOS transistor P2.

Since the gate of the fifth NMOS transistor N5 may be connected to the drain of the fifth NMOS transistor N5 and the gate of the sixth PMOS transistor N6, the fifth NMOS transistor N5 and the sixth NMOS transistor N6 may form a second current mirror. That is, the main driver current I_MD, which is M times the second current I_2 flowing in the fifth NMOS transistor N5, may flow in the sixth NMOS transistor N6. Here, M may vary according to processes, structures, and the like of the fifth NMOS transistor N5 and the sixth NMOS transistor N6.

Accordingly, the first main driver circuit 332B_1 may allow the main driver current I_MD, which is N*M times the first current I_1 flowing in the first PMOS transistor P1, to flow to the sixth NMOS transistor N6, through the first and second current mirrors.

The first capacitor C1 of the first pre-emphasis circuit 331B_1 may be connected to the gate and the source of the first PMOS transistor P1 and the gate of the second PMOS transistor P2, and the second capacitor C2 may be connected to the gate and drain of the fifth NMOS transistor N5, and the gate and drain of the sixth NMOS transistor N6.

The first pre-emphasis circuit 331B_1 may transmit the first emphasis signal ES_1 to the first node ND1 through the first capacitor C1. In addition, the first pre-emphasis circuit 331B_1 may transmit the second emphasis signal ES_2 to the second node ND2 through the second capacitor C2. The first emphasis signal ES_1 may be generated by allowing the pre-emphasis signal VPRE to pass through the first capacitor C1, and the second emphasis signal ES_2 may be generated by allowing the pre-emphasis signal VPRE to pass through the first inverter INV1 and the second capacitor C2. Accordingly, the phases of the first empress signal ES_1 and the second empress signal ES_2 may be opposite to each other.

When the first emphasis signal ES_1 pulls up the first node ND1, the second emphasis signal ES_2 may pull down the second node ND2. Likewise, when the first emphasis signal ES_1 pulls down the first node ND1, the second emphasis signal ES_2 may pull up the second node ND2.

For example, when the first emphasis signal ES_1 pulls down the first node ND1, a voltage level of the first node ND1 may be lowered, and a gate voltage level of the gate of the first PMOS transistor P1 and a gate voltage level of the gate of the second PMOS transistor P2, which are connected to the first node ND1, may be lowered. Accordingly, channels of the first PMOS transistor P1 and the second PMOS transistor P2 may be further widened. Accordingly, since the amount of the first current I_1 may increase, the second current I_2 that is N times the first current I_1 may increase. In addition, since the second emphasis signal ES_2 may pull up the second node ND2, a voltage level of the second node ND2 may be increased, and a gate voltage level of the gate of the fifth NMOS transistor N5 and a gate voltage level of the gate of the sixth NMOS transistor N6, which are connected to the second node ND2, may be increased. Accordingly, channels of the fifth NMOS transistor N5 and the sixth NMOS transistor N6 may be further widened. Accordingly, since the amount of the second current I_2 may be increased, the main driver current I_MD, which is M times the second current I_2, may be increased.

When the first emphasis signal ES_1 pulls up the first node ND1, a voltage level of the first node ND1 may be increased, and a gate voltage level of the gate of the first PMOS transistor P1 and a gate voltage level of the gate of the second PMOS transistor P2, which are connected to the first node ND1, may be increased. Accordingly, channels of the first PMOS transistor P1 and the second PMOS transistor P2 may be further reduced. Accordingly, since the amount of the first current I_1 may be reduced, the second current I_2 that is N times the first current I_1 may be reduced. In addition, since the second emphasis signal ES_2 may pull down the second node ND_2, a gate voltage level of the gate of the fifth NMOS transistor N5 and a gate voltage level of the gate of the sixth NMOS transistor N6, which are connected to the second node ND_2, may be lowered. Accordingly, channels of the fifth NMOS transistor N5 and the sixth NMOS transistor N6 may be further reduced. Since the amount of the second current I_2 may be reduced, the main driver current I_MD, which is M times the second current I_2, may be reduced.

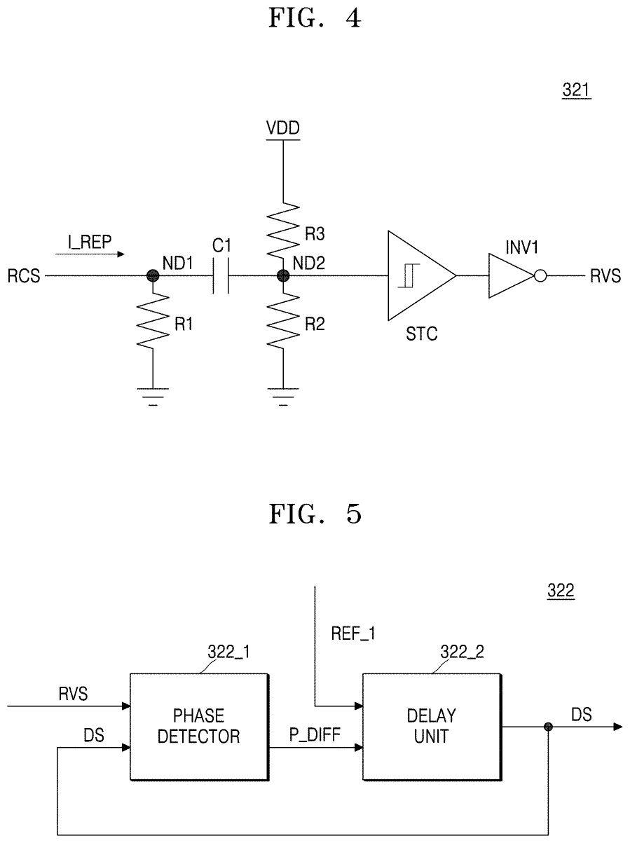

FIG. 4 is a circuit diagram illustrating a current-voltage conversion circuit 321 according to an embodiment. The current-voltage conversion circuit 321 may include first to third resistors R1 to R3, a first capacitor C1, a Schmidt trigger circuit STC, and a first inverter INV1.

Referring to FIGS. 1 and 4, the current-voltage conversion circuit 321 may receive a replica current I_REP and a replica voltage signal RCS corresponding to the replica current I_REP, which are transferred from the drive circuit 130. A direct-current (DC) component of the replica current I_REP may flow from the first node ND1 to the ground through the first resistor R1, and the AC component of the replica current I_REP may be transferred from the first node ND1 to the second node ND2 through the first capacitor C1. A bias voltage of

$$\frac{R 2}{R 2 + R 3} * V D D$$

may be applied to the second node ND2 by voltage distribution. Accordingly, a signal having a voltage level obtained by adding a bias voltage of

$$\frac{R 2}{R 2 + R 3} * V D D$$

and a voltage corresponding to the AC component of the replica current I_REP may be applied to the second node ND2. The signal applied to the second node ND2 may be an analog signal. The signal applied to the second node ND2 may be converted into a digital signal through the Schmidt trigger circuit STC. The Schmidt trigger circuit STC may output a signal having a high logic level when a voltage level of a signal applied to the second node ND2 is equal to or greater than a reference voltage, and may output a signal having a low logic level when the voltage level is lower or equal to than the reference voltage. The signal output from the Schmidt trigger circuit STC may be converted into the replica voltage signal RVS via the first inverter INV1. As a result, the current-voltage conversion circuit 321 may receive the replica current I_REP, which is an analog signal, and output the replica voltage signal RVS, which is a digital signal.

FIG. 5 is a block diagram illustrating a delay-locked loop (DLL) circuit according to an embodiment.

Referring to FIG. 5, the DLL circuit 322 may include a phase detector 322_1 and a delay unit 322_2.

As illustrated in FIG. 5, the phase detector 322_1 may receive a replica voltage signal RVS from the current-voltage conversion circuit 121 and receive a driving signal DS from the delay unit 322_2. The phase detector 322_1 may detect the phase of the replica voltage signal RVS and the phase of the driving signal DS to generate a phase difference signal P_DIFF having information on a phase difference between the two signals. The phase detector 322_1 may provide the phase difference signal P_DIFF to the delay unit 322_2.

As shown in FIG. 5, the delay unit 322_2 may receive a first reference signal REF1 from the preprocessing circuit 110 and receive a phase difference signal P_DIFF from the phase detector 322_1. The delay unit 322_2 may shift the phase of the first reference signal REF1 by the phase corresponding to the phase difference signal P_DIFF to generate the driving signal DS. The first reference signal REF1 may include a positive first reference signal and a negative first reference signal. The delay unit 322_2 may generate a calibrated driving signal DS by shifting the phase of the positive first reference signal or the negative first reference signal. For example, the delay unit 322_2 may generate a calibrated driving signal DS by shifting the phase of the positive first reference signal by a phase difference between the replica voltage signal RVS and the driving signal DS based on the phase difference signal P_DIFF.

In the example embodiment, when the magnitude of the phase difference between the replica voltage signal RVS and the driving signal DS is greater than the magnitude of the phase in which the delay unit 3222_2 may shift at a time, the DLL circuit 322 may repeatedly perform the operation. That is, the DLL circuit 322 may repeatedly perform operations of detecting a phase difference between the replica voltage signal RVS and the driving signal DS and shifting a phase of the first reference signal REF1.

As a result, the DLL circuit 322 detects a phase difference between the driving signal DS and the replica voltage signal RVS and generates the driving signal DS having a phase that is shifted by the phase difference between the two signals, thereby reducing the phase difference between the driving signal DS and the replica voltage signal RVS.

FIG. 6 is a calibration timing diagram according to an embodiment. FIG. 6 will be described with reference to FIGS. 1 to 5 described above.

The input signal INPUT may include a positive input signal P_INPUT and a negative input signal N_INPUT having a phase opposite to that of the positive input signal P_INPUT. The positive input signal P_INPUT and the negative input signal N_INPUT may be signals that are repeated at the same period.

Referring to FIGS. 5 and 6, when the phase difference between the replica voltage signal RVS and the driving signal DS is greater than the magnitude of the phase that the delay unit 322_2 may shift at a time, the DLL circuit 322 may repeatedly perform the operations of detecting the phase difference between the replica voltage signal RVS and the driving signal DS and shifting the phase of the first reference signal REF1. For example, in FIG. 6, calibration was performed over four time intervals, that is, over the first time intervals t1 to t3, the second time intervals t3 to t5, the third time intervals t5 to t7, and the fourth time intervals t7 to t9. Calibration may be performed during the first to fourth time intervals to reduce timing mismatch between the replica voltage signal RVS and the driving signal DS. That is, the timing mismatch may gradually decrease as it goes from the first timing mismatch t1 to t2 in the first time interval, to the second timing mismatch t3 to t4 in the second time interval, to the third timing mismatch t5 to t6 in the third time interval, and to the fourth timing mismatch t7 to t8 in the fourth time interval.

Referring to FIGS. 2 and 6, the driving current I_VC may be represented as the sum of the bias current I_BIAS and the main driver current I_MD.

Since the bias current I_BIAS may have a constant current level during the first to fourth time intervals, a waveform of the main driver current I_MD may be the same as a waveform of the driving current I_VC.

During the calibration, the rise time of the driving current I_VC may be reduced. That is, during the calibration, the slew rate of the driving current I_VC may increase. Here, the slew rate may mean a maximum change rate of the output signal.

Through the calibration operation, the driving signal DS may be calibrated to instantaneously increase/decrease the driving current I_VC in accordance with the rise/fall timing of the driving current I_VC.

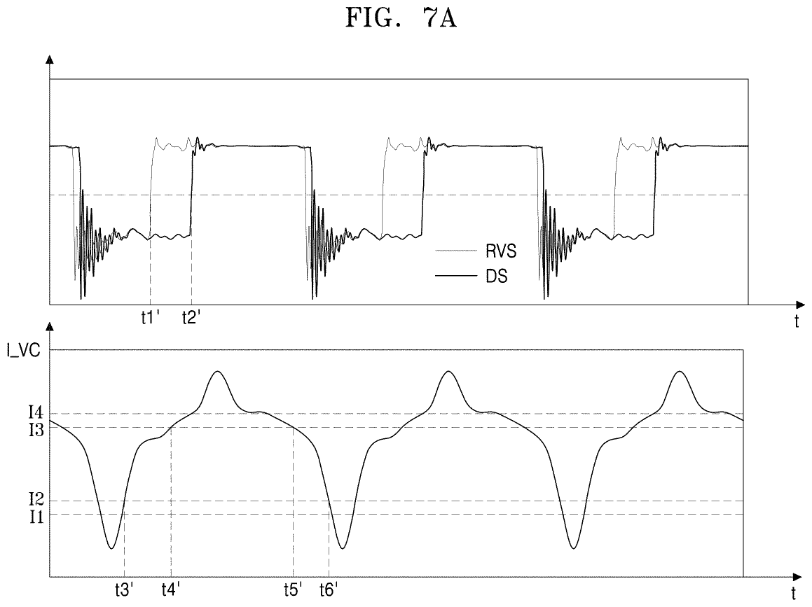

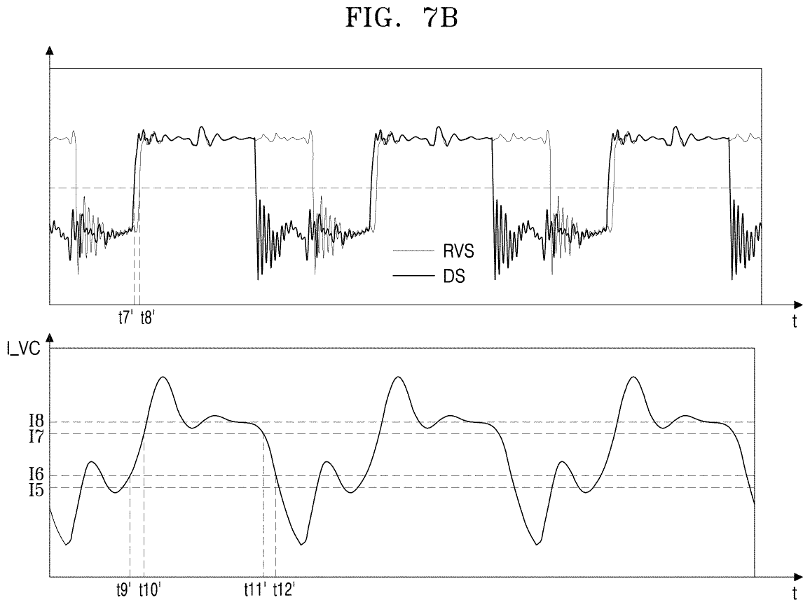

FIGS. 7A and 7B are diagrams illustrating a calibration result according to an embodiment. FIG. 7A shows graphs of a replica voltage signal RVS, a driving signal DS, and a driving current I_VC over time before being calibrated, and FIG. 7B shows graphs over time after the calibration.

In FIG. 7A, a timing mismatch between the replica voltage signal RVS and the driving signal DS may be a time interval of t1′ to t2′, and a time period during which the driving current I_VC rises from 12 to 13 may be a time interval of t3′ to t4′. The time during which the driving current I_VC descends from 13 to 12 may be at time intervals of t5′ to t6′.

In FIG. 7B, a timing mismatch between the replica voltage signal RVS and the driving signal DS may be a time interval of t7′ to t8′, and a time period during which the driving current I_VC rises from 16 to 17 may be a time interval of t9′ to t10′. The time during which the driving current I_VC descends from 17 to 16 may be at time intervals of t11′ to t12′.

The replica voltage signal RVS may be a conversion of a driving current I_VC, which is a current signal, into a voltage signal. The drive apparatus 100 may match the rise timing of the replica voltage signal RVS and the driving signal DS to apply the driving signal DS to the drive circuit 130 according to the rise timing of the driving current I_VC. Accordingly, the drive apparatus 100 may allow the pre-emphasis circuit 131 to instantaneously increase the driving current I_VC according to the rise timing of the driving current I_VC due to the timing mismatch.

FIG. 7B illustrates a case in which the driving signal DS is calibrated according to the rise timing of the driving current I_VC. However, even when the driving signal DS is calibrated in accordance with the fall timing of the driving current I_VC, it will be understood by one of ordinary skill in the art that the calibration is performed by the method described in the present disclosure.

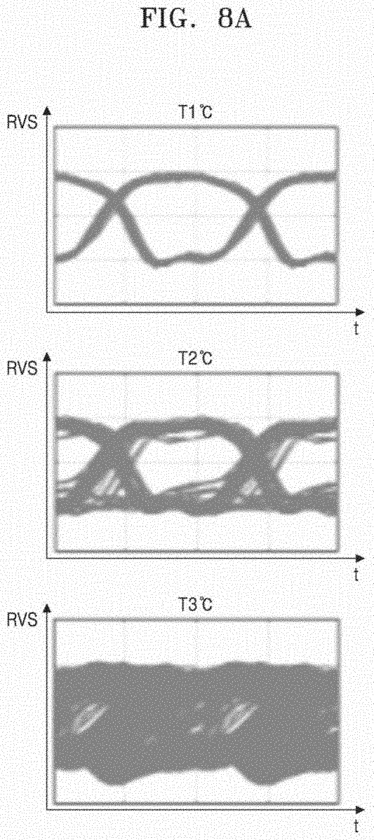

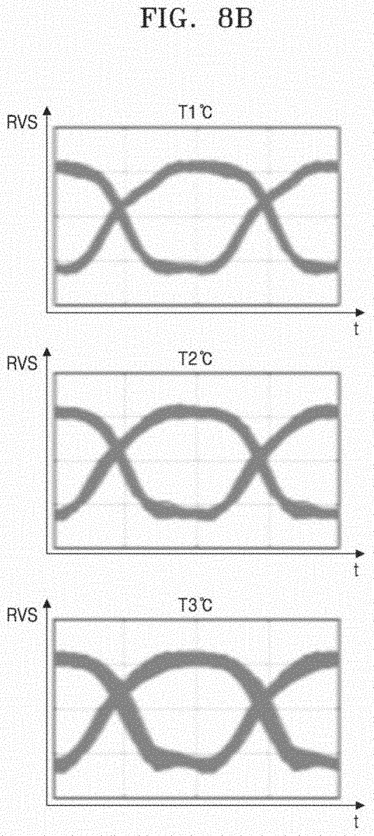

FIGS. 8A and 8B are diagrams illustrating a calibration result according to an embodiment. FIGS. 8A to 8B show replica voltage signals RVS at different temperatures over time. FIG. 8A shows the replica voltage signal RVS before the calibration, and FIG. 8B shows the replica voltage signal RVS after the calibration. The temperatures T1, T2, and T3 of the drive apparatus 100 shown in FIGS. 8A and 8B may satisfy the relationship of T1<T2<T3. FIGS. 8A and 8B may be described with reference to FIG. 1.

In FIG. 8A, as the temperature of the replica voltage signal RVS gradually increases to T1, T2, and T3, the eye of the replica voltage signal RVS may gradually become smaller. Here, when the accumulated waveform of the signal is displayed on the time axis, the eye may mean the waveform shown in the same shape as the eye. When the size of the eye is large, it may mean that distortion of the signal is small. In FIG. 8A, the decrease in the eye of the replica voltage signal RVS may mean that the distortion of the replica voltage signal RVS increases.

In the case of FIG. 8B, even if the temperature gradually increases to T1, T2, and T3, the eye of the replica voltage signal RVS may be constant compared to FIG. 8A. This may mean that, in the case of calibration, even if the temperature gradually increases to T1, T2, and T3, the replica voltage signal RVS is hardly distorted.

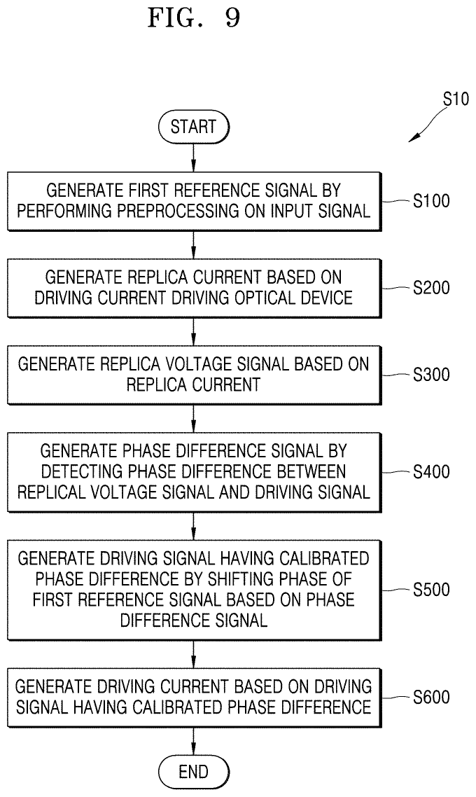

FIG. 9 is a flowchart illustrating a method of operating a drive apparatus 100, according to an embodiment. FIG. 9 will be described with reference to FIGS. 1 to 5 described above.

The operation method S10 of the drive apparatus 100 may include operations S100 to S600.

In operation S100, the first reference signal REF1 may be generated by performing preprocessing on the input signal INPUT. Operation S100 may be performed through the preprocessing circuit 110 of FIG. 1. The preprocessing circuit 110 may amplify the input signal INPUT by performing preprocessing on the input signal INPUT. In addition, the preprocessing circuit 110 may reduce an effect of noise, which is generated by a circuit connected to the preprocessing circuit 110, influencing the input signal INPUT.

In operation S200, the replica current I_REP may be generated based on the driving current I_VC driving the optical device 200. Operation S200 may be performed by the current mirror circuit 344A_1 of FIG. 2. Since the bias current I_BIAS may be a DC current, the waveform of the current, that is, the replica current I_REP, may be the same as the waveform of the driving current I_VC. Accordingly, the current mirror circuit 344_1 may generate the replica current I_REP based on the main driver current I_MD, which is a part of the driving current I_VC.

In operation S300, the replica voltage signal RVS may be generated based on the replica current I_REP. Operation S300 may be performed by the current-voltage conversion circuit 321 of FIG. 4. The current-voltage conversion circuit 321 may receive the replica current I_REP, which is an analog signal, and output the replica voltage signal RVS, which is a digital signal.

In operation S400, the phase of the driving signal DS may be calibrated so that the phase of the driving signal DS coincides with the phase of the replica voltage signal RVS. Operation S400 may be performed by the DLL circuit 322 of FIG. 5. The DLL circuit 322 may receive the replica voltage signal RVS and the first reference signal REF1. The DLL circuit 322 may detect a phase difference between the driving signal DS, which is an output signal of the DLL circuit 322, and the replica voltage signal RVS, which is an input signal of the DLL circuit 322, and generate a phase difference signal P_DIFF having information on the phase difference.

In operation S500, a driving signal DS having a calibrated phase difference may be generated. The DLL circuit 322 may shift a phase of the first reference signal REF1 by a phase difference based on the phase difference signal P_DIFF and the first reference signal REF1 to generate a driving signal DS of which the phase difference is calibrated.

In operation S600, the drive circuit 130 may generate the driving current I_VC based on the driving signal DS generated in operation S500. In some embodiments, the operation method S10 of the drive apparatus 100 may further include generating emphasis signals ES_1 and ES_2 when the driving signal DS rises or falls, based on the driving signal DS generated in operation S500. As illustrated in FIG. 3, the emphasis signals ES_1 and ES_2 may be generated by extracting an AC component of the driving signal DS. The drive circuit 130 may reduce the rise/fall time of the driving current I_VC by using the empress signals ES_1 and ES_2.

In another embodiment, the method S10 of operating the drive apparatus 100 may further include generating a second reference signal REF2 by performing preprocessing on the input signal INPUT, and adjusting the driving current I_VC based on the second reference signal REF2 and the driving signal DS. The generating of the second reference signal REF2 by performing a preprocessing of the input signal INPUT may be performed by the preprocessing circuit 110 of FIG. 1, and the adjusting of the driving current I_VC based on the driving signal DS may be performed by the first pre-emphasis circuit 331B_1 and the first main driver circuit 332B_1 of FIG. 3.

FIG. 10 is a block diagram illustrating a distance measurement sensor according to an embodiment.

A distance measurement sensor 1000 may include a controller 400, a drive apparatus 500, an optical device 600, and an image sensor 700.

The controller 400 may be a hardware processor. The controller 400 may generate at least one drive apparatus control signal DA_CON and provide the same to the drive apparatus 500. The at least one drive apparatus control signal DA_CON may include the input signal INPUT of FIG. 1 or the enable signal EN of FIG. 2. The controller 400 may control the level of the second driving current I_VC by adjusting the enable signal EN.

The drive apparatus 500 may be the drive apparatus 500 described above with reference to FIGS. 1 to 5. The drive apparatus 500 may generate the first driving current I_VC1 based on at least one drive apparatus control signal DA_CON and may provide the first driving current I_VC1 to the optical device 600. In addition, the drive apparatus 500 may generate the second driving current I_VC2 based on the first driving current I_VC1 and the at least one drive apparatus control signal DA_CON. In this case, the slew rate of the second driving current I_VC2 may be greater than the slew rate of the first driving current I_VC1.

Specifically, as shown in FIG. 1, the drive apparatus 500 may include a drive circuit 130 generating a replica current I_REP based on the first driving current I_VC1 and a calibration circuit 120 generating a replica voltage signal RVS based on the replica current I_REF and providing, to the drive circuit 130, a driving signal DS generated by changing the phase of the drive apparatus control signal DA_CON based on the replica voltage signal RVS. The drive circuit 130 may provide, to the optical device 600, the second driving current I_VC2 generated based on the driving signal DS.

Here, as described above with reference to FIG. 2, the drive circuit 130 may include pre-emphasis circuits 331A_1 to 331A_P for generating emphasis signals ES_1 and ES_2 when the driving signal DS rises or falls, and bias circuits 333A_1 to 333A_R for generating a bias current and providing the same to the optical device 600.

In addition, as described above with reference to FIG. 1, the calibration circuit 120 may include the current-voltage conversion circuit 121 that generates the replica voltage signal RVS based on the replica current I_REP and the DLL circuit 122 that generates the driving signal DS by changing the phase of the at least one drive apparatus control signal DA_CON based on the replica voltage signal RVS.

As described above with reference to FIG. 5, the DLL circuit 122 may include a phase detector 322_1 that detects a phase difference between the driving signal DS and the replica voltage signal RVS to generate a phase difference signal P_DIFF and a delay unit 322_2 that changes the phase of at least one drive apparatus control signal DA_CON based on the phase difference signal P_DIFF to generate a driving signal DS.

The distance measurement sensor 1000 may measure the distance between the distance measurement sensor 1000 and an object 2000 by measuring the reflection signal RS reflected after the optical output signal OS output from the optical device 600 reaches the object 2000. Specifically, the optical device 600 may output, to the object 2000, the optical output signal OS generated based on the second driving current I_VC2. The image sensor 700 may receive the reflection signal RS generated when the optical output signal OS is reflected after reaching the object 2000. The distance measurement sensor 1000 may measure a distance to the object 2000 by measuring a time taken from a time when the optical output signal OS is output to a time when the reflection signal RS is received.

While example embodiments have been particularly shown and described, it will be understood that various changes in form and details may be made therein without departing from the spirit and scope of the following claims.

What is claimed is:

1. A drive apparatus configured to drive an optical device, the drive apparatus comprising:
a preprocessing circuit configured to generate a first reference signal by performing preprocessing on an input signal;
a drive circuit configured to generate a driving current for driving the optical device, and generate a replica current based on the driving current; and
a calibration circuit configured to generate a replica voltage signal based on the replica current, generate a driving signal by changing a phase of the first reference signal based on the replica voltage signal, and provide the driving signal to the drive circuit.

2. The drive apparatus of claim 1, wherein the drive circuit comprises:
at least one pre-emphasis circuit configured to generate an emphasis signal based on the driving signal rising or falling; and
at least one unit drive circuit configured to generate a replica current based on the emphasis signal and the driving current.

3. The drive apparatus of claim 2, wherein the pre-emphasis circuit comprises at least one first capacitor configured to generate the emphasis signal based on the driving signal rising or falling, and provide the emphasis signal to the at least one unit drive circuit.

4. The drive apparatus of claim 3, wherein the pre-emphasis circuit further comprises a level shift circuit connected between the at least one first capacitor and input terminals of the pre-emphasis circuit, wherein the level shift circuit is configured to pull up or pull down a voltage level of the driving signal.

5. The drive apparatus of claim 1, wherein the input signal comprises a first input signal and a second input signal having a phase opposite to a phase of the first input signal,
wherein the preprocessing circuit is further configured to generate a second reference signal based on the first input signal and the second input signal, and
wherein the drive circuit is further configured to control the driving current based on the second reference signal and the driving signal.

6. The drive apparatus of claim 1, wherein the drive circuit comprises a bias circuit configured to generate a bias current and provide the bias current to the optical device.

7. The drive apparatus of claim 1, wherein the calibration circuit comprises:
a current-voltage conversion circuit configured to convert the replica current to generate the replica voltage signal; and
a delayed locked loop (DLL) circuit configured to generate the driving signal based on the first reference signal and the replica voltage signal.

8. The drive apparatus of claim 7, wherein the DLL circuit comprises:
a phase detector configured to generate a phase difference signal indicative of a phase difference between the driving signal and the replica voltage signal; and
a delay unit configured to generate the driving signal by shifting the phase of the first reference signal by the phase difference based on the phase difference signal.

9. The drive apparatus of claim 1, wherein the optical device comprises a vertical cavity surface emitting laser (VCSEL).

10. A distance measurement sensor comprising:
an optical device;
a controller configured to generate at least one drive apparatus control signal; and
a drive apparatus configured to generate a first driving current based on the at least one drive apparatus control signal and provide the first driving current to the optical device,
wherein the drive apparatus comprises:
a drive circuit configured to generate a replica current based on the first driving current; and
a calibration circuit configured to generate a replica voltage signal based on the replica current, generate a driving signal by changing a phase of the at least one drive apparatus control signal based on the replica voltage signal, and provide the driving signal to the drive circuit,
wherein the drive circuit is further configured to generate a second driving current based on the driving signal, and provide the second driving current to the optical device, and
wherein a slew rate of the second driving current is greater than a slew rate of the first driving current.

11. The distance measurement sensor of claim 10, wherein the at least one drive apparatus control signal comprises an enable signal, and
wherein the controller is further configured to control a level of the second driving current by adjusting the enable signal.

12. The distance measurement sensor of claim 10, wherein the optical device is configured to generate an optical output signal based on the second driving current, and output the optical output signal to an object, and
wherein the distance measurement sensor further comprises an image sensor configured to receive a reflection signal of the optical output signal reflected by the object.

13. The distance measurement sensor of claim 12, wherein the distance measurement sensor is configured to measure a distance to the object based on a time when the optical output signal is output and a time when the reflection signal is received.

14. The distance measurement sensor of claim 10, wherein the drive circuit further comprises at least one pre-emphasis circuit configured to generate an emphasis signal based on the driving signal rising or falling.

15. The distance measurement sensor of claim 10, wherein the calibration circuit comprises:
a current-voltage conversion circuit configured to generate the replica voltage signal based on the replica current; and
a delayed locked loop (DLL) circuit configured to generate the driving signal by changing the phase of the at least one drive apparatus control signal based on the replica voltage signal.

16. The distance measurement sensor of claim 15, wherein the DLL circuit comprises:
a phase detector configured to detect a phase difference between the driving signal and the replica voltage signal to generate a phase difference signal; and
a delay unit configured to generate the driving signal by changing the phase of the at least one drive apparatus control signal based on the phase difference signal.

17. A method of operating a drive apparatus configured to drive an optical device, the method comprising:
generating a first reference signal by performing preprocessing on an input signal;
generating a replica current based on a driving current driving the optical device;
generating a replica voltage signal based on the replica current;
generating a phase difference signal by detecting a phase difference between the replica voltage signal and a driving signal;
generating a calibrated driving signal by shifting a phase of the first reference signal based on the phase difference signal; and
generating the driving current based on the calibrated driving signal.

18. The method of claim 17, further comprising generating an emphasis signal based on the calibrated driving signal rising or falling.

19. The method of claim 18, wherein the generating the emphasis signal comprises generating the emphasis signal by extracting an alternating-current (AC) component of the calibrated driving signal.

20. The method of claim 17, further comprising generating a second reference signal by performing preprocessing on the input signal,
wherein the generating the driving current comprises generating the driving current based further on the second reference signal.
